(19) United States
(12) Patent Application Publication
(10) Pub. No.: US 2025/0245806 A1
(43) Pub. Date: Jul. 31, 2025

(54) SUBSTRATE DETECTION METHOD AND LOAD PORT

(71) Applicant: Sinfonia Technology Co., Ltd., Tokyo (JP)

(72) Inventors: Keigo Sato; Yuji Miyashita, Tokyo (JP); Katsumi Yasuda, Tokyo (JP); Mitsutoshi Ochiai, Tokyo (JP)

(73) Assignee: Sinfonia Technology Co., Ltd., Tokyo (JP)

(21) Appl. No.: 18/845,844

(22) PCT Filed: Mar. 3, 2023
(86) PCT No.: PCT/JP2023/008114

§ 371 Date: Sep. 10, 2024

(30) Foreign Application Priority Data
Mar. 11, 2022 (JP) 2022-037793

(51) Int. Cl. G06T 7/00; G06T 7/70

(52) U.S. Cl. CPC G06T 7/0004; G06T 7/70; G06T 2207/30148; G06T 2207/30242

(57) ABSTRACT

A detection method of a wafer detects whether or not the wafer is a double wafer based on first imaging data, which is obtained by imaging the wafer accommodated in a slot in an FOUP from above, and second imaging data obtained by imaging the wafer from below. When the wafer is a double wafer, a state in which an upper wafer protrudes from a lower wafer and a converse state in which the lower wafer protrudes from the upper wafer can be considered. In any of the states, both the upper wafer and the lower wafer are captured in at least one of the first imaging data or the second imaging data. Thus, by performing, for example, image analysis based on the first imaging data and the second imaging data, it is possible to accurately detect a double wafer for each wafer.

### TECHNICAL FIELD

The present application relates to a technique for detecting a semiconductor substrate (hereinafter referred to as “substrate”) accommodated in a container.

### BACKGROUND

Patent Document 1 discloses a load port including a mapping sensor integrally provided with a door, which moves vertically between a closing position where the door closes an opening in communication with an interior of a container for storing a plurality of wafers as an example of substrates in multiple stages and an opening position where the door opens the opening, and configured to detect a state of the wafers, the mapping sensor including a light emitting part that irradiates light for imaging toward the wafers and an imaging part that captures an image by imaging an illumination region illuminated by the light emitting part.

### PRIOR ART DOCUMENT

### Patent Document

Patent Document 1: Japanese Patent Laid-open Publication No. 2019-102753

However, in the load port disclosed in Patent Document 1, when each substrate accommodated in the container is imaged by the mapping sensor, variation in a vertical position of each substrate in the container is not taken into consideration. Therefore, it may be determined that a single substrate is accommodated in one slot, despite the fact that two substrates are accommodated in one slot (also known as a “double state”).

FIG. 9 shows a state in which an installation position of a slot SL for accommodating a wafer in a container has a variation, and an imaging position of a camera 20 is shifted upward from a position of the wafer to be imaged. In this state, when the camera 20 images a wafer W3, which is a double wafer, a lower wafer W3B is hidden behind an upper wafer W3A, and only the upper wafer W3A is captured in a captured image. Therefore, when image analysis is conducted on this captured image, the wafer W3 is determined to be accommodated alone in the container, resulting in an erroneous determination.

The present application provides a technique capable of accurately detecting an accommodation status of substrates in a container.

### SUMMARY

A substrate detection method according to a present application includes: detecting an accommodation state of a substrate based on first imaging data obtained by imaging the substrate accommodated in a slot of a container from a first height and second imaging data obtained by imaging the substrate from a second height.

When the substrate is in a double state, there may be a state in which an upper substrate protrudes from a lower substrate and a state in which the lower substrate protrudes from the upper substrate. In either state, both the upper substrate and the lower substrate will be captured in at least one of the first imaging data or the second imaging data. Therefore, by performing, for example, image analysis based on the first imaging data and the second imaging data, it is possible to accurately detect the accommodation state of the substrate, particularly the double state.

In addition, the first imaging data may be obtained by imaging at a position within an upper limit of a range of variation from an accommodation position of the substrate to be imaged in the container, and the second imaging data may be obtained by imaging at a position within a lower limit of the range of variation from the accommodation position of the substrate to be imaged in the container.

With this configuration, the first imaging data and the second imaging data are obtained by imaging the same substrate at different heights. Thus, it is possible to accurately detect that the substrate is in a double state based on the first imaging data and the second imaging data.

In addition, the first imaging data may be obtained by imaging at an accommodation position of a substrate which is accommodated a predetermined number of stages ahead of the substrate to be imaged, and the second imaging data may be obtained by imaging at an accommodation position of a substrate which is accommodated a predetermined number of stages behind the substrate to be imaged.

With this configuration, the first imaging data is obtained by imaging the substrate as a detection target for a double state from above, and the second imaging data is obtained by imaging the substrate as the detection target for the double state from below. Thus, it is possible to accurately detect that the substrate is in a double state based on the first imaging data and the second imaging data.

In addition, the first imaging data and the second imaging data may be obtained by imaging by an imaging device integrally installed with a door, which moves vertically between a closing position where the door closes an opening of the container and an open position where the door opens the opening, and an imaging position of the imaging device may be calculated based on position information for the door detected when the door moves vertically.

With this configuration, it is possible to recognize the imaging position of the imaging device without using any special means or method only for detecting the imaging position of the imaging device. Thus, it is possible to accurately align the imaging device with the imaging position and capture an image while reducing manufacturing costs of an apparatus.

A substrate detection method according to the present disclosure is a method of detecting an accommodation state of a substrate accommodated in a slot of a container, and includes: imaging the substrate from a first height to acquire first imaging data; imaging the substrate from a second height to acquire second imaging data; detecting the number of substrates captured in the first imaging data and the second imaging data; and determining whether or not there is an abnormality in the number of substrates captured in the first imaging data and the second imaging data.

With this configuration, it is possible to accurately detect the accommodation state of the substrate, particularly, the double state, and to determine whether or not there is an abnormality based on the detection results.

A load port according to the present disclosure includes: a container configured to accommodate substrates in multiple stages; an imaging device configured to image the substrates accommodated in the container; and a controller configured to control the imaging device to image the substrate from a first height and image the substrate from a second height to acquire first imaging data and second imaging data, respectively, from the imaging device, and detect an accommodation state of the substrate based on the acquired first imaging data and the acquired second imaging data.

With this configuration, it is possible to accurately detect the accommodation state of the substrate, particularly the double state.

### BRIEF DESCRIPTION OF DRAWINGS

FIG. 1 is a side sectional view of a load port according to an embodiment of the present application.

FIG. 2 is a side sectional view showing a state in which a door is moved downward together with a lid of an FOUP from the state shown in FIG. 1.

FIG. 3 is a view showing an example of a positional relationship among a camera shown in FIG. 1, a lighting, and a wafer to be imaged.

FIG. 4 is a block diagram showing a control configuration of the load port shown in FIG. 1.

FIG. 5 is a flowchart showing a sequence of a first double wafer detection process executed by a controller shown in FIG. 4, particularly a CPU.

FIGS. 6A and 6B are schematic diagrams showing states in which the first double wafer detection process shown in FIG. 5 is being executed.

FIG. 7 is a flowchart showing a sequence of a second double wafer detection process executed by the controller shown in FIG. 4, particularly the CPU.

FIGS. 8A and 8B are schematic diagrams showing states in which the second double wafer detection process shown in FIG. 7 is being executed.

FIG. 9 is a diagram for explaining a case where a conventional load port cannot detect a double wafer.

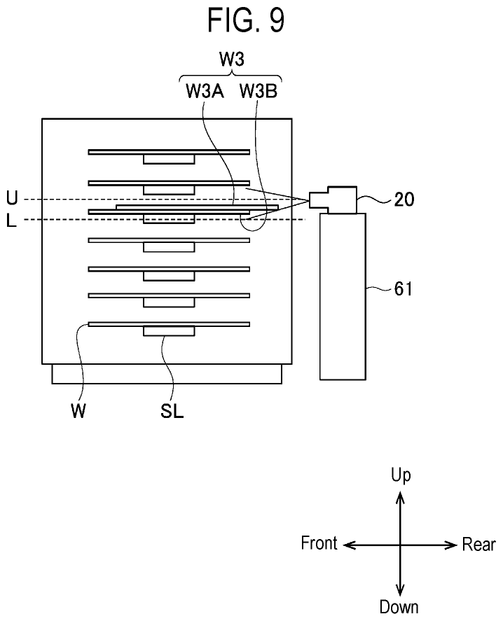

### DETAILED DESCRIPTION

Embodiments of the present application will now be described in detail with reference to the accompanying drawings.

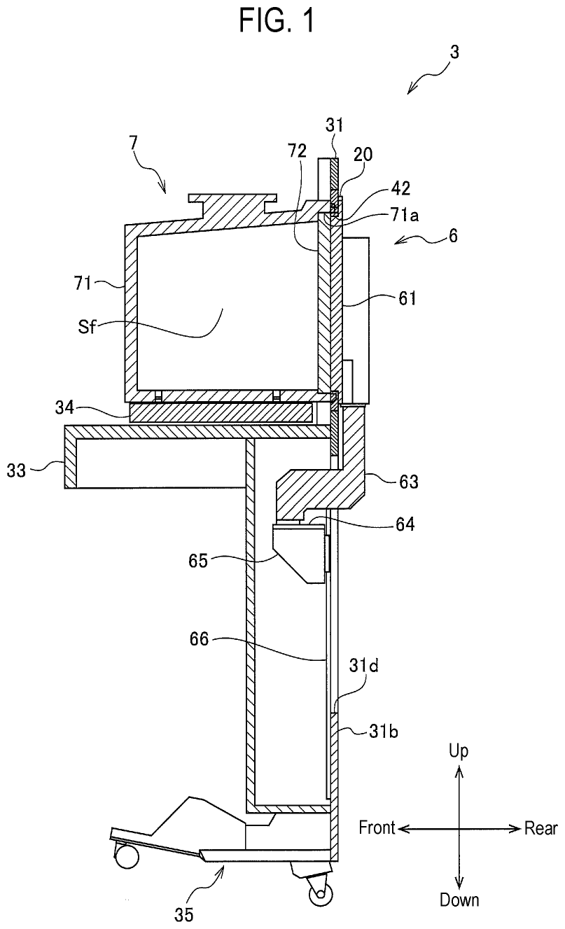

FIG. 1 shows a side cross section of a load port 3 according to an embodiment of the present application. The load port 3 is attached to a semiconductor manufacturing apparatus (not shown) that performs various processes on wafers, and serves as an interface between a front-opening unified pod (FOUP) 7 that accommodates a plurality of wafers and the semiconductor manufacturing apparatus. In addition, when directions are mentioned in each figure, directions of arrows shown in each figure are used.

In the load port 3, a panel 31 is erected vertically from a rear side of a leg 35, to which casters and installation legs are attached, and a horizontal base 33 is provided to face forward at a height position of about 60% of a height of the panel 31. In addition, a stage 34 for placing an FOUP 7 thereon is provided above the horizontal base 33.

The FOUP 7 is constituted by a main body 71 having an internal space Sf for accommodating wafers W, and a lid 72 capable of closing an opening 71a formed on one surface of the main body 71 to serve as a loading/unloading port for the wafers W. When the FOUP 7 is properly placed on the stage 34, the lid 72 faces the panel 31. In addition, the stage 34 is movable in a front-rear direction with the FOUP 7 placed thereon.

The load port 3 includes an opening/closing mechanism 6 for opening and closing an opening 42. The opening/closing mechanism 6 includes a door 61 for opening and closing the opening 42, a support frame 63 for supporting the door 61, a movable block 65 for supporting the support frame 63 via a slide support 64 so that the support frame 63 is movable in the front-rear direction, and a slide rail 66 for supporting the movable block 65 so that the movable block 65 is movable in an up-down direction with respect to a panel main body 31b. The support frame 63 supports a rear lower portion of the door 61, and has a substantially crank-like shape that extends downward and then protrudes toward a front side of the panel main body 31b via a slit-shaped insertion hole 31d provided in the panel main body 31b. Further, the slide support 64, the movable block 65, and the slide rail 66 for supporting the support frame 63 are provided on a front side of the panel main body 31b.

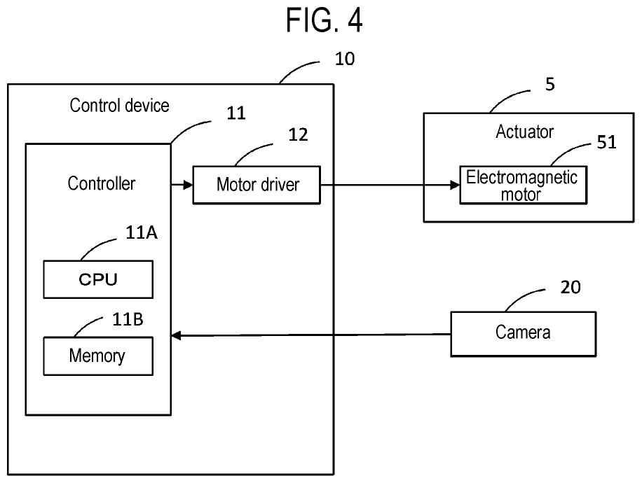

In addition, actuators 5 (see FIG. 4) for moving the door 61 in the front-rear direction and the up-down direction are provided for the respective directions, and by giving drive commands to these actuators from a controller 11, it is possible to move the door 61 in the front-rear direction and the up-down direction.

The door 61 includes a connection means (not shown) for performing a latch operation of opening and closing the lid 72 of the FOUP 7 and an operation of holding the lid 72. By the connection means, it is possible to bring the lid 72 into an openable state by attracting the lid 72, and to connect the lid 72 to the door 61 to bring the lid 72 and the door 61 into an integrated state. Conversely, it is also possible to release the connection between the lid 72 and the door, and to attach the lid 72 to the main body 71 to bring the main body 71 into a closed state.

In addition, by operating the connection means, the attraction of the lid 72 is released so that the lid 72 can be removed from the main body 71, and the lid 72 is held integrally by the door 61. In this state, the door 61 is moved rearward together with the support frame 63. In the manner described above, it is possible to distance the lid 72 of the FOUP 7 away from the main body 71 to open the internal space Sf.

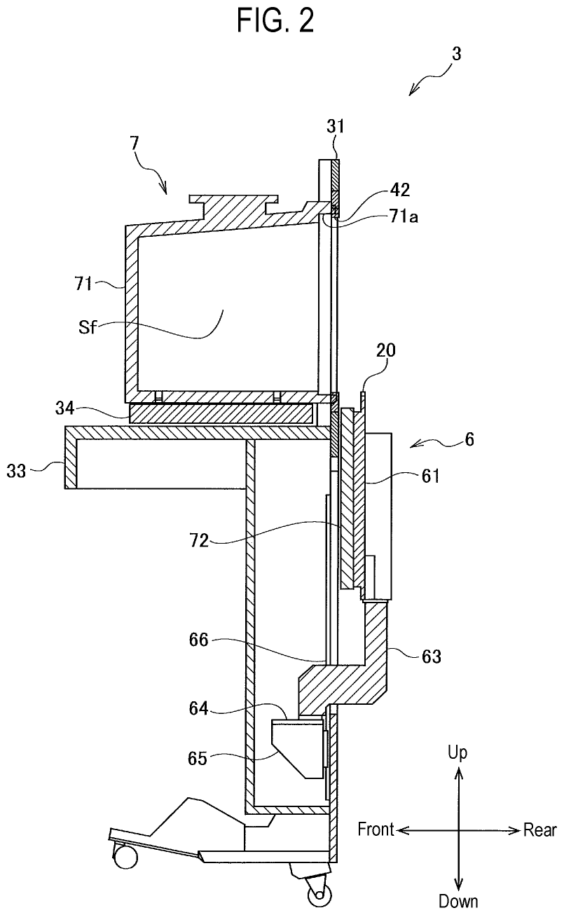

In addition, as shown in FIG. 2, the door 61 is moved downward together with the support frame 63. In the manner described above, a rear side of the opening 71a, which serves as the loading/unloading port of the FOUP 7, can be widely opened, it is possible to move a wafer between the FOUP 7 and a semiconductor manufacturing apparatus. Operations performed when opening the opening 71a of the FOUP 7 have been described above. When closing the opening 71a of the FOUP 7, operations reverse to those described above may be performed.

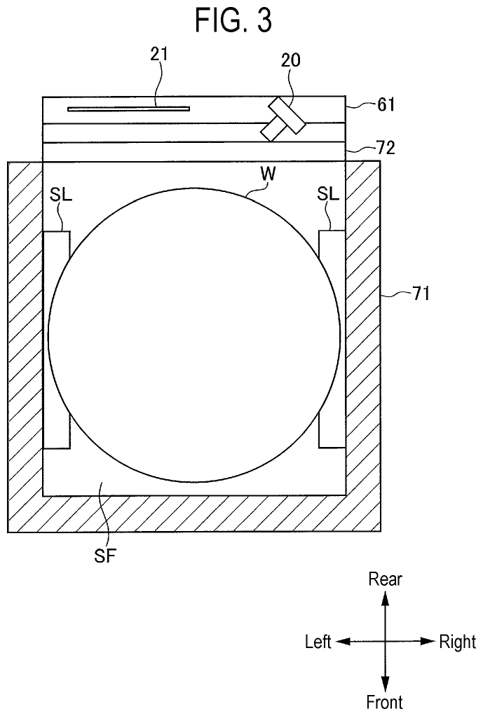

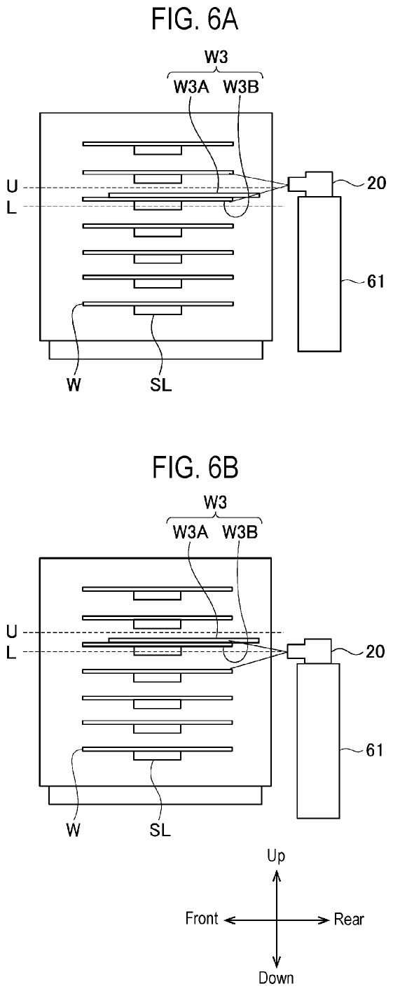

In an upper edge portion of the door 61, as shown in FIG. 3, the camera 20 and the lighting 21 are fixed integrally with the door 61. Specifically, the camera 20 is fixed to a potion on a right-hand side of a center of the upper edge portion of the door 61 in the left-right direction perpendicular to the front-rear direction, and the lighting 21 is fixed to a portion on a left-hand side of the center by, for example, a known fastening means (not shown). Therefore, when the door 61 is closing the opening 42, i.e., when the opening 71a of the FOUP 7 is in the closed state, the camera 20 and the lighting 21 are disposed above the uppermost wafer W among the plurality of wafers W (see FIGS. 6A and 6B) accommodated in the FOUP 7. Further, the camera 20 is disposed to face a direction in which the wafer W is imaged obliquely. One reason for disposing the camera 20 in the manner described above is that when the wafer W is imaged from a front thereof, reflected light from a sidewall of the FOUP 7 is projected in imaging data, making it difficult to image the wafer W properly. Another reason is that when the wafer W is imaged from the front, a distance between the wafer W and the camera 20 is too close, making it difficult to perform focusing. By imaging the wafer W obliquely, the distance between the wafer W and the camera 20 becomes long, making it easier to perform focusing. The effects described above are the same to rectangular substrates other than the wafer W. In the present embodiment, the lighting 21 is formed in a wide shape using, for example, an LED tape. The lighting 21 irradiates light onto the wafer W accommodated in the FOUP 7, so that in imaging data obtained by imaging the wafer W with the camera 20, the wafer W can be recognized by image recognition.

The camera 20 is controlled by the controller 11 to capture an image of each wafer W accommodated in the FOUP 7 while the door 61 moves horizontally backward and then downward.

FIG. 4 shows a control configuration for the load port 3. The load port 3 includes a control device 10, which in turn includes the controller 11 and a motor driver 12. The controller 11 is connected to the motor driver 12, and the motor driver 12 is connected to an electromagnetic motor 51 that constitutes the actuator 5. Further, the controller 11 is connected to the camera 20.

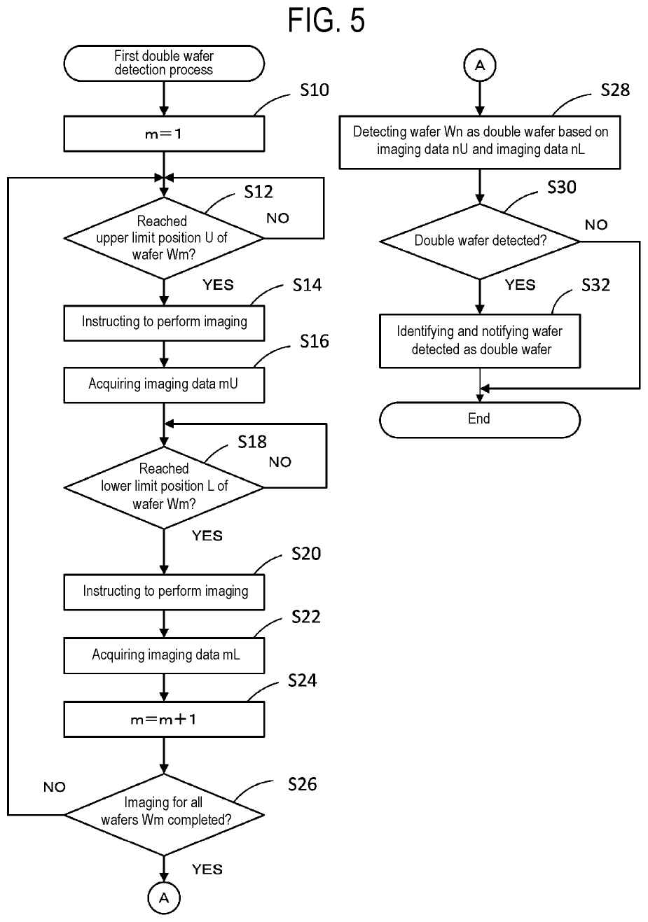

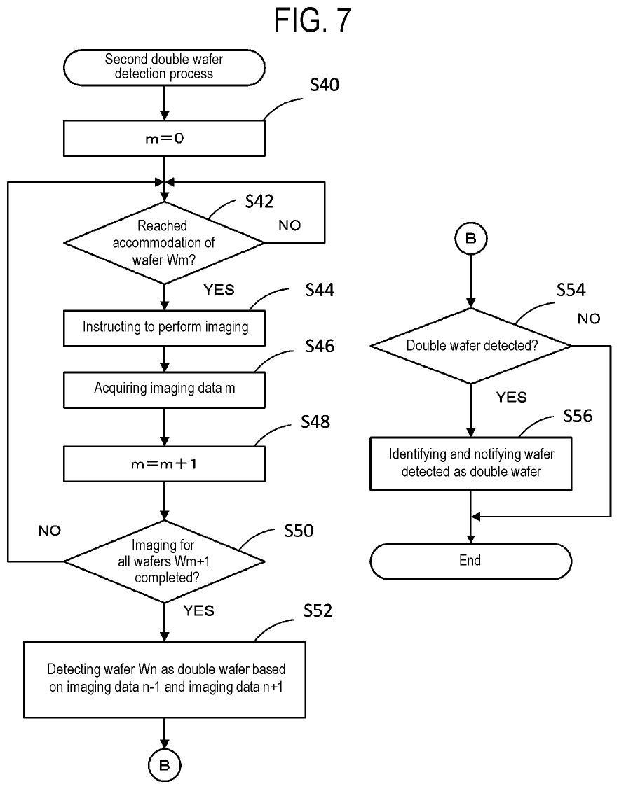

The controller 11 includes a CPU 11A and a memory 11B. The memory 11B includes, for example, a RAM, a ROM, a flash memory, and the like, and stores information relating to control and processing. Further, the memory 11B stores control programs and the like for executing various control processes including first and second double wafer detection processes (see FIGS. 5 and 7) to be described later. The CPU 11A performs various controls for the load port 3 by executing the various control programs stored in the memory 11B.

The controller 11 controls the electromagnetic motor 51 via the motor driver 12 in the process of performing various controls for the load port 3. In the present embodiment, the electromagnetic motor 51 is used as a power source when the actuator 5 moves the door 61 in the up-down direction. For example, when a stepping motor is adopted as the electromagnetic motor 51, the controller 11 supplies a pulse signal to the motor driver 12. The motor driver 12 controls a rotary shaft of the stepping motor so that a rotation angle corresponds to the number of pulses of the input pulse signal. Therefore, the controller 11 can indirectly know a current position of the door 61 in the up-down direction by accumulating the number of pulses of the pulse signal supplied to the motor driver 12 (including accumulating negative values). Accordingly, since the controller 11 can also recognize a current position of the camera 20, it is possible to capture an image by the camera 20 at any position ranging from a position where the door 61 fully closes the opening 42 to a position where the door 61 fully opens the opening 42.

The imaging data obtained by the camera 20 is transmitted from the camera 20 to the controller 11. The controller 11 temporarily stores the imaging data received from the camera 20 in the memory 11B. Then, the controller 11 performs image processing on the imaging data stored in the memory 11B, and determines whether or not each wafer W accommodated in each slot SL is a double wafer.

The control process configured as described above and executed by the load port 3 will be described in detail with reference to FIGS. 5 to 8B. FIG. 5 shows a sequence of a first double wafer detection process executed by the controller 11, particularly, by the CPU 11A. The first double wafer detection process is started at a predetermined timing before a transfer of the wafer W from the FOUP 7 begins, for example, at a timing when the door 61 of the load port 3 moves vertically to open the lid 72 of the FOUP 7. Hereinafter, in the description of the sequence of each process, a step will be represented as “S.”

In FIG. 5, first, the CPU 11A sets a counter m, which is for counting wafers W accommodated in the FOUP 7 stage by stage sequentially from above, to an initial value of “1” (S10).

Subsequently, the CPU 11A determines whether the imaging position of the camera 20 has reached an upper limit position U of a wafer Wm (S12). Here, the wafer Wm refers to a wafer W accommodated in a slot SL of a stage indicated by the current counter m. That is, when m=1, the wafer Wm is a wafer W1, which indicates a wafer W accommodated in the slot SL of the uppermost stage. Further, the upper limit position U is an upper limit position generated by variation in an installation position of the slot SL. That is, the upper limit position U indicates an upper limit of a position shifted upward from a designed installation position due to the variation. Further, since a range of the variation is defined in advance, when the designed installation position is known, the upper limit position generated by the variation can be specified.

In the determination of S12 described above, when the imaging position of the camera 20 has not yet reached the upper limit position U of the wafer Wm (S12: “NO”), the CPU 11A waits until it reaches the upper limit position U of the wafer Wm. When the imaging position of the camera 20 has reached the upper limit position U of the wafer Wm (S12: “YES”), the CPU 11A instructs the camera 20 to capture an image at that position (S14). Then, the CPU 11A acquires imaging data mU captured by the camera 20 from the camera 20 (S16), and temporarily stores the imaging data in, for example, the memory 11B. FIG. 6A shows a state in which the camera 20 has reached the upper limit position U of a wafer W3 stored in the slot SL of the third stage from above and is capturing an image at that position.

Subsequently, the CPU 11A determines whether the imaging position of the camera 20 has reached a lower limit position L of the wafer Wm (S18). The lower limit position L is a lower limit position generated by the variation in the installation position of the slot SL. When the imaging position of the camera 20 has not yet reached the lower limit position L of the wafer Wm (S18: “NO”), the CPU 11A waits until it reaches the lower limit position L of the wafer Wm. When the imaging position of the camera 20 has reached the lower limit position L of the wafer Wm (S18: “YES”), the CPU 11A instructs the camera 20 to capture an image at that position (S20), obtains imaging data mL captured by the camera 20 from the camera 20 (S22), and temporarily stores the imaging data in, for example, the memory 11B. FIG. 6B shows a state in which the camera 20 has reached the lower limit position L of the wafer W3 stored in the slot SL of the third stage from above and is capturing an image at that position.

Subsequently, the CPU 11A advances the count value of the counter m by “1” (S24), and then determines whether imaging for all wafers Wm accommodated in the FOUP 7 has been completed, in other words, whether imaging for the wafer W at the lowermost position has been completed (S26). Since the number of stages for the wafers W accommodated in the FOUP 7 is known, the determination in S26 can be easily made by comparing the value of the counter m with the number of stages. In this determination, when there remain wafers W to be imaged (S26: “NO”), the CPU 11A returns the process to S12 and repeats the process from S12 onwards. On the other hand, when the imaging for all wafers Wm has been completed (S26: “YES”), the CPU 11A advances the process to S28.

In S28, the CPU 11A detects whether the wafer Wn is a double wafer based on imaging data nU and imaging data nL temporarily stored in the memory 11B. When the wafer Wn is a double wafer, given that the upper wafer Wn is a wafer WnA and the lower wafer Wn is a wafer WnB, there may be a state in which the upper wafer WnA protrudes closer to the camera 20 than the lower wafer WnB, and a state in which the lower wafer WnB protrudes closer to the camera 20 than the upper wafer WnA. The example of FIGS. 6A and 6B shows a state in which the upper wafer W3A protrudes closer to the camera 20 than the lower wafer W3B. In the example of FIGS. 6A and 6B, in imaging data 3U, only the upper wafer W3A is captured, and the lower wafer W3B is not captured because the lower wafer W3B is in a blind spot of the upper wafer W3A. On the other hand, since imaging data 3L is taken by the camera 20 at the lower limit position L of the wafer W3, in the imaging data 3L, the lower wafer W3B is not in the blind spot of the upper wafer W3A, and both the wafers W3A and W3B are captured. Contrary to the example of FIGS. 6A and 6B, in a state in which the lower wafer W3B protrudes closer to the camera 20 than the upper wafer W3A, in the imaging data 3L, only the lower wafer W3B is captured, and the upper wafer W3A is not captured because the upper wafer W3A is in a blind spot of the lower wafer W3B. On the other hand, since the imaging data 3U is taken by the camera 20 at the upper limit position U of the wafer W3, in the imaging data 3U, the lower wafer W3B is not in the blind spot of the upper wafer W3A, and both the wafers W3A and W3B are captured. As described above, when the wafer Wn is a double wafer, at least one of the imaging data nU or the imaging data nL captures both the upper wafer WnA and the lower wafer WnB. Therefore, by performing image analysis on the imaging data nU and the imaging data nL, it is possible to detect that the wafer Wn is a double wafer.

In addition, in the process of S28, while changing the wafer Wn to be detected, the upper limit position and the lower limit position of the wafer Wn are imaged to obtain the image data nU and the image data nL. After imaging for all the wafers W is completed, detecting a double wafer is performed with respect to from the uppermost wafer W to the lowermost wafer W. Therefore, a plurality of double wafers W may be detected.

Subsequently, the CPU 11A determines whether or not a double wafer has been detected (S30). When the double wafer has been detected (S30: “YES”), the CPU 11A identifies and notifies the slot SL in which the wafer W detected as a double wafer is accommodated (S32). Then, the first double wafer detection process is terminated. As the notification method, for example, a display notification method or a voice notification method can be considered, and any method may be adopted.

On the other hand, when it is determined in S32 that a double wafer has not been detected (S30: “NO”), the CPU 11A terminates the first double wafer detection process.

As described above, according to the first double wafer detection process, even when there is a variation in the installation position of the slot SL in the FOUP 7 and therefore there is a variation in an accommodation position of the wafer W in the up-down direction, it is possible to accurately detect that the accommodated wafer W is a double wafer. In addition, in the first double wafer detection process, images are captured when the imaging position of the camera 20 accurately reaches the upper limit position U and the lower limit position L of each wafer W. However, the present disclosure is not limited thereto, and images may be captured at a position slightly below the upper limit position U and a position slightly above the lower limit position L, as long as it is possible to detect a double wafer by using at least one of the image data U obtained by imaging at the position slightly below the upper limit position U or the image data L obtained by imaging at the position slightly above the lower limit position L.

FIG. 7 shows a sequence of a second double wafer detection process executed by the controller 11, particularly, the CPU 11A. The second double wafer detection process is similar to the first double wafer detection process in that it accurately detects whether or not the wafer W accommodated in the FOUP 7 is a double wafer, but is different from the first double wafer detection process in that the number of times the camera 20 captures the image of the wafer W is reduced. The first double wafer detection process and the second double wafer detection process are not performed in parallel, and it may be sufficient to perform either one of them to detect whether or not the wafer W accommodated in the FOUP 7 is a double wafer. A timing to start the second double wafer detection process may be the same as the timing to start the first double wafer detection process.

Referring to FIG. 7, first, the CPU 11A sets a counter m to an initial value of “0” (S40). The counter m functions in the same way as the counter m defined in the first double wafer detection process. However, the initial value of the counter m is different from the initial value in the first double wafer detection process.

Subsequently, the CPU 11A determines whether the imaging position of the camera 20 has reached an accommodation position of the wafer Wm (S42). The accommodation position of the wafer Wm is a position where the wafer Wm is accommodated when the slot SL is installed at a designed installation position thereof. An accommodation position of the wafer WO when m=0 means an imaginary accommodation position that is one stage ahead of an accommodation position of the uppermost wafer W1.

In the determination of S42 described above, when the imaging position of the camera 20 has not yet reached the accommodation position of the wafer Wm (S42: “NO”), the CPU 11A waits until the camera 20 reaches the accommodation position. When the imaging position of the camera 20 reaches the accommodation position of the wafer Wm (S42: “YES”), CPU 11A instructs the camera 20 to capture an image at that position (S44). In the imaging instruction in S14 or S20 of the first double wafer detection process described above, an angle of view of the camera 20 may be within a range in which a wafer Wm+a accommodated in the slot SL of one stage is imaged, whereas in S44. On the contrary, in S44, it is necessary that an angle of view of the camera 20 is within a range in which three sheets of wafers Wm−1 to Wm+1 or more accommodated in the slots SL of three stages or more are imaged.

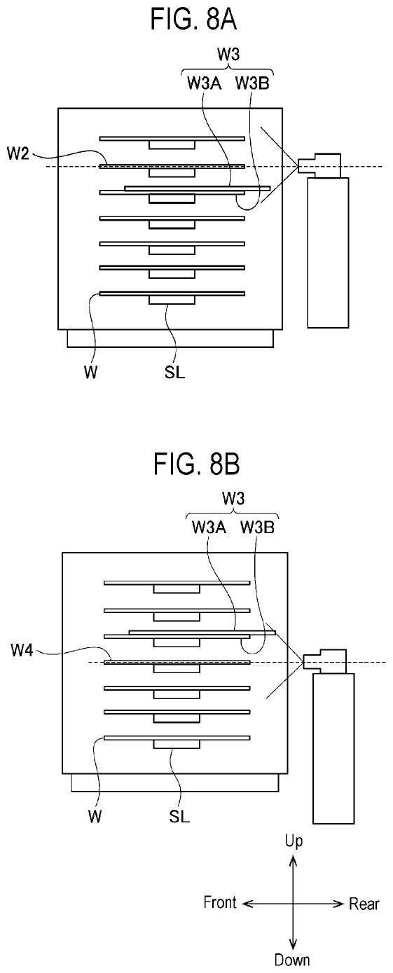

Then, the CPU 11A acquires, from the camera 20, image data m obtained by imaging by the camera 20 (S46), and temporarily stores the data in, for example, the memory 11B. FIG. 8A shows a state in which the camera 20 has reached the accommodation position of the wafer W2 accommodated in the slot SL of the second stage from above and is capturing an image at that position.

Subsequently, the CPU 11A advances the count value of the counter m by “1” (S48), and then determines whether imaging for all wafers Wm+1 accommodated in the FOUP 7 has been completed (S50). Here, the term all wafers Wm+1 refers to an imaginary wafer W one stage behind the lowermost wafer W. In the determination of S50, when there still remains a wafer W to be imaged (S50: “NO”), the CPU 11A returns the process to S42 and repeats the process from S42 onwards. On the other hand, when the imaging for all wafers Wm+1 has been completed (S50: “YES”), the CPU 11A advances the process to S52. As described above, in the second double wafer detection process, imaging is also performed at an accommodation position of the imaginary wafer W one stage behind the lowermost wafer W, and imaging data m at that position is obtained.

In S52, the CPU 11A detects whether or not a wafer Wn is a double wafer based on imaging data n−1 and imaging data n+1, among all imaging data including two pieces of imaging data at the imaginary accommodation positions of the wafer W, which are temporarily stored in the memory 11B. That is, detecting whether or not the wafer Wn is a double wafer is performed based on the imaging data n−1 obtained by imaging the wafer Wn−1 accommodated in the slot SL of one stage ahead and the imaging data n+1 obtained by imaging the wafer Wn+1 accommodated in the slot SL of one stage behind.

FIG. 8B shows a state in which the camera 20 reaches an accommodation position of the wafer W4 accommodated in the slot SL of the fourth stage from above and is capturing an image at that position. Detecting whether or not the wafer W3 is a double wafer is performed based on imaging data 2 obtained by imaging at the imaging position of FIG. 8A and imaging data 4 obtained by imaging at the imaging position of FIG. 8B. As shown in FIGS. 8A and 8B, with respect to the wafer W3, a state of the wafer W3 imaged by the camera 20 from above the wafer W3 is captured in the imaging data 1, and a state of the wafer W3 imaged by the camera 20 from below the wafer W3 is captured in the imaging data 4. Therefore, when the wafer W3 is a double wafer and the upper wafer W3A protrudes closer to the camera 20 than the lower wafer W3B as in the example of FIGS. 8A and 8B, only the upper wafer W3A is captured in the imaging data 2, and the lower wafer W3B is not captured because the lower wafer W3B is in the blind spot of the upper wafer W3A. On the other hand, in the imaging data 4, the lower wafer W3B is not in the blind spot of the upper wafer W3A, and both the wafers W3A and W3B are captured. Contrary to the example of FIGS. 8A and 8B, when the lower wafer W3B protrudes closer to the camera 20 than the upper wafer W3A, only the lower wafer W3B is captured in the imaging data 4, and the upper wafer W3A is not captured because the upper wafer W3A is in the blind spot of the lower wafer W3B. On the other hand, in the imaging data 2, the lower wafer W3B is not in the blind spot of the upper wafer W3A, and both the wafers W3A and W3B are captured. As described above, when the wafer Wn is a double wafer, at least one of the imaging data n−1 o the imaging data n+1 captures both the upper wafer WmA and the lower wafer WmB. Therefore, by performing image analysis on the imaging data n−1 and the imaging data n+1, it is possible to detect that the wafer Wn is a double wafer.

In addition, in the process of S52, while changing the wafer Wn to be imaged, imaging data n is acquired by imaging a range of wafers Wn−1 to Wn+1, which includes the wafer Wn and wafers one stage above and one stage below the wafer Wn, or more. After imaging for all wafers W is completed, a double wafer is detected from the uppermost wafer W to the lowermost wafer W. Therefore, a plurality of wafers W as double wafers W may be detected.

Subsequent processes in S54 and S56 are similar to those in S30 and S32 of the first double wafer detection process, and therefore description of the processes will be omitted.

As described above, according to the second double wafer detection process, even when there is a variation in the installation position of the slot SL in the FOUP 7 and therefore there is a variation in the accommodation position of the wafer W in the up-down direction, it is possible to accurately detect that the accommodated wafer W is a double wafer. In addition, in the first double wafer detection process, the number of pieces of image data is twice the number of wafers W accommodated in the FOUP 7 (a double wafer is also counted as one), whereas in the second double wafer detection process, the number of pieces of image data is equal to the number of wafers W accommodated in the FOUP 7 (a double wafer is also counted as one)+2. Therefore, the number of imaging times in the second double wafer detection process is reduced compared to the number of imaging times in the first double wafer detection process.

As described above, the method of detecting the wafer W according to the present embodiment detects the wafer W as a double wafer based on the first imaging data obtained by imaging the wafer W accommodated in the slot SL in the FOUP 7 from above and the second imaging data obtained by imaging the wafer W from below. In addition, in the present embodiment, the wafer W is an example of a “substrate.” The FOUP 7 is an example of a “container.” The upper side is an example of a “first height.” The lower side is an example of a “second height.” The double wafer is an example of an “accommodation state.”

When the wafer W is a double wafer, a state in which the upper wafer WA protrudes from the lower wafer WB and a state in which the lower wafer WB protrudes from the upper wafer WA can be considered. In either state, both the upper wafer WA and the lower wafer WB are imaged in at least one of the first imaging data or the second imaging data. Therefore, by performing, for example, image analysis based on the first imaging data and the second imaging data, it is possible to accurately detect whether each wafer W is a double wafer.

In addition, the imaging data mU is obtained by imaging at the upper limit position U of a range within which the accommodation position of the wafer W to be imaged varies in the FOUP 7, and the imaging data mL is obtained by imaging at the lower limit position L of the range within which the accommodation position of the wafer W to be imaged varies in the FOUP 7. In addition, the imaging data mU is an example of “first imaging data.” The upper limit position U is an example of “a position within an upper limit.” The imaging data mL is an example of “second imaging data.” The lower limit position L is an example of “a position within a lower limit.”

Accordingly, the imaging data mU is obtained by imaging each wafer W from above, and the imaging data mL is obtained by imaging each wafer W from below. A double wafer can be accurately detected for each wafer W based on the imaging data mU and the imaging data mL.

In addition, the imaging data n−1 is obtained by imaging at an accommodation position of a wafer accommodated one stage ahead of the wafer W to be imaged, and the imaging data n+1 is obtained by imaging at an accommodation position of a wafer accommodated one stage behind the wafer W to be imaged. In addition, the imaging data n−1 is an example of “first imaging data.” The imaging data n+1 is an example of “second imaging data.” One stage is an example of a “predetermined number of stages.”

Accordingly, the imaging data n−1 is obtained by imaging the wafer as a double wafer detection target from above, and the imaging data n+1 is obtained by imaging the wafer as a double wafer detection target from below. A double wafer can be accurately detected for each wafer W based on the imaging data n−1 and the imaging data n+1.

In addition, the first and second imaging data are obtained by imaging using the camera 20 integrally provided on the door 61, which moves vertically between a closing position where the door 61 closes the opening 71a provided in the FOUP 7 and an open position where the door 61 opens the opening 71a. The imaging position of the camera 20 is calculated based on position information for the door 61, which is detected when the door 61 moves vertically. In addition, the opening 71a is an example of an “opening portion.” The camera 20 is an example of an “imaging device.”

Accordingly, since the imaging position of the camera 20 can be recognized without using any special means or method only for detecting the imaging position of the camera 20, it is possible to accurately align the imaging device with the imaging position and capture an image while suppressing manufacturing costs of an apparatus.

The present disclosure is not limited to the above-described embodiments, and various modifications may be made without departing from the spirit of the present disclosure.

(1) In the above-described embodiments, the FOUP 7 is used as a container for accommodating the wafers W. However, other containers such as a Front Opening Shipping Box (FOSB) and the like may also be used.

(2) In the above-described embodiments, a stepping motor has been described as an example of the electromagnetic motor 51. However, the present disclosure is not limited thereto, and a servo motor may be used. In this case, a current position of the door 61 in the up-down direction may be indirectly recognized based on information obtained from an encoder. Further, in the case where a sensor, for example, is provided to directly detect the current position of the door 61 in the up-down direction, a current position of the camera 20 may be calculated based on an output from the sensor.

(3) In the above-described embodiments, the camera 20 and the lighting 21 are configured as separate entities. However, the present disclosure is not limited thereto, and a mapping sensor including a camera and a lighting may be adopted to capture an image of the wafer W in the FOUP 7 by the mapping sensor.

(4) In the above-described embodiments, it is assumed that each slot SL in the FOUP 7 accommodates the wafer W. However, the present disclosure is not limited thereto, and an image of a slot SL that does not accommodate a wafer W may also be captured by the camera 20. When it is detected that an image of a wafer W is not captured in imaging data, the slot SL may be identified and notified.

(5) In the above-described embodiments, the present disclosure has been described using the wafer W as an example of a detection target. However, the present disclosure is not limited thereto, and may be applied to rectangular substrates such as glass substrates, resin substrates, and liquid crystal substrates.

(6) In the above-described embodiments, the camera 20 is moved from top to bottom to capture images of the wafers W. However, the order of capturing images is not limited thereto. The camera may be moved from bottom to top to capture images, or the order may be set arbitrarily by an operator.

### EXPLANATION OF REFERENCE NUMERALS

3: load port, 5: actuator, 6: opening/closing mechanism, 7: FOUP, 10: control device, 11: controller, 11A: CPU, 11B: memory, 12: motor driver, 20: camera, 21: lighting, 51: electromagnetic motor, 61: door, 72: lid, SL: slot, W: wafer

1. A substrate detection method, comprising:
detecting an accommodation state of a substrate based on first imaging data obtained by imaging the substrate accommodated in a slot of a container from a first height and second imaging data obtained by imaging the substrate from a second height.

2. The substrate detection method of claim 1, wherein the first imaging data is obtained by imaging at a position within an upper limit of a range of variation from an accommodation position of the substrate to be imaged in the container, and
wherein the second imaging data is obtained by imaging at a position within a lower limit of the range of variation from the accommodation position of the substrate to be imaged in the container.

3. The substrate detection method of claim 1, wherein the first imaging data is obtained by imaging at an accommodation position of a substrate which is accommodated a predetermined number of stages ahead of the substrate to be imaged, and
wherein the second imaging data is obtained by imaging at an accommodation position of a substrate which is accommodated the predetermined number of stages behind the substrate to be imaged.

4. The substrate detection method of claim 1, wherein the first imaging data and the second imaging data are obtained by imaging by an imaging device integrally provided with a door, which moves vertically between a closing position where the door closes an opening of the container and an open position where the door opens the opening, and
wherein an imaging position of the imaging device is calculated based on position information for the door, which is detected when the door moves vertically.

5. A substrate detection method of detecting an accommodation state of a substrate accommodated in a slot of a container, comprising:
imaging the substrate from a first height to acquire first imaging data;
imaging the substrate from a second height to acquire second imaging data;
detecting the number of substrates captured in the first imaging data and the second imaging data; and
determining whether or not there is an abnormality in the number of substrates captured in the first imaging data and the second imaging data.

6. A load port, comprising:
a container configured to accommodate substrates in multiple stages;
an imaging device configured to image a substrate accommodated in the container; and
a controller configured to control the imaging device to image the substrate from a first height and image the substrate from a second height to acquire first imaging data and second imaging data, respectively, from the imaging device, and detect an accommodation state of the substrate based on the acquired first imaging data and the acquired second imaging data.

7. The substrate detection method of claim 2, wherein the first imaging data and the second imaging data are obtained by imaging by an imaging device integrally provided with a door, which moves vertically between a closing position where the door closes an opening of the container and an open position where the door opens the opening, and
wherein an imaging position of the imaging device is calculated based on position information for the door, which is detected when the door moves vertically.

8. The substrate detection method of claim 3, wherein the first imaging data and the second imaging data are obtained by imaging by an imaging device integrally provided with a door, which moves vertically between a closing position where the door closes an opening of the container and an open position where the door opens the opening, and
wherein an imaging position of the imaging device is calculated based on position information for the door, which is detected when the door moves vertically.
